(19) United States
(12) Patent Application Publication
(10) Pub. No.: US 2026/0262190 A1
(43) Pub. Date: Sep. 3, 2026

(54) ASSEMBLY AND METHOD FOR CONTROLLING THE TESTING TEMPERATURE OF ELECTRONIC COMPONENTS

(71) Applicant: Ciena Corporation, Hanover, MD (US)

(72) Inventors: Joel Priddle, Kanata (CA); Don Lentz, Westport (CA)

(21) Appl. No.: 19/068,150

(22) Filed: Mar. 3, 2025

(51) Int. Cl. H05K 7/20; G01R 31/28

(52) U.S. Cl. CPC H05K 7/20254; G01R 31/28; H05K 7/20154; H05K 7/20209; H05K 7/20281

(57) ABSTRACT

A thermal testing assembly for an electronic component, including a thermoelectric cooler having a temperature control side and a heat rejection side, a pedestal structure including an integrated cold plate disposed on and in thermal communication with the temperature control side of the thermoelectric cooler, and a heat dissipating member disposed on and in thermal communication with the heat rejection side of the thermoelectric cooler, where the thermoelectric cooler and/or the integrated cold plate are adapted to be operated to control a temperature of a unit under test disposed adjacent to and in thermal communication with the pedestal structure opposite the thermoelectric cooler. Coolant from a chiller may be circulated through the integrated cold plate to cool the unit under test through the pedestal structure. The thermoelectric cooler may be operated to cool or heat the unit under test through the pedestal structure and coolant disposed within the integrated cold plate.

### TECHNICAL FIELD

The present disclosure relates generally to the telecommunications, networking, and electronics fields. More particularly, the present disclosure relates to an assembly and method for controlling the testing temperature of electronic components.

### BACKGROUND

There are a few conventional approaches to control the testing temperature of an electronic component, or a unit under test (UUT). Some of these approaches work well in some applications, while other of these approaches work well in other applications, with all of these approaches being limited in some testing of high-power optical sub-assemblies, for example. For such high-power optical sub-assemblies, testing at different temperatures is important to ensure functionality. Some products, such as the optical components used in plugs and modems, must be tested/calibrated at multiple different temperatures to ensure that the products work well in any intended working temperature range and to weed out bad parts before putting them into another assembly or sub-assembly.

The UUT may be disposed in a thermal (environmental) chamber that allows for control of the ambient temperature to control the testing temperature of the UUT. This method may be used in combination with other methods. Limitations of thermal chamber methodologies include slow temperature ramp rates (resulting in longer testing times while waiting for the testing temperature to change), limited working space (equipment needs to be disposed within the thermal chamber or wires routed into the thermal chamber), and high cost.

A heatsink may be thermally coupled to the UUT and associated fans may be operated at varying speeds to provide a cooling airflow to control the testing temperature of the UUT. Limitations of the heatsink methodologies include an inability to cool below ambient temperature without the additional use of a thermal chamber.

A cold plate may be thermally coupled to the UUT and the temperature of the associated coolant may be varied to control the testing temperature of the UUT. Since chillers and coolant are used to control the cold plate temperature, standard chillers typically do not have a wide enough operating temperature range to cover the whole testing temperature range (e.g., a plug may be tested from −20 C to 85 C, but no standard chiller can control the coolant temperature over that entire testing temperature range—standard chiller temperature ranges are often 5 C to 40 C and wide-temperature range chillers are often less efficient. Even if an expensive custom chiller is available that works over the entire testing temperature range, using coolant at 85 C with a burning time of a few seconds means that many extra precautions have to be taken. Further, one chiller must be provided per UUT, or, if one expensive chiller is used for multiple UUTs, they all have to be tested at the same temperature at the same time. Another way to vary the cold plate temperature to vary the UUT temperature is to vary the flowrate of the coolant to the cold plate. While this is possible, practically it is very complicated to develop a robust design for testing without a lot of extra design and control complexity. Essentially, cold plates are very efficient at transferring energy, so extremely low flowrates are utilized to get the cold plate to raise in temperature to test at higher temperatures. Controlling such low flowrates is very difficult. Since the flowrate is so low, heat loss in the tubing tends to throw off the temperature, and a large amount of time is needed to get to steady state temperature for testing.

Finally, a thermal head assembly utilizing a thermoelectric cooler (TEC) may be thermally coupled to the UUT and actuated to control the testing temperature of the UUT. TECs work by transferring heat energy from one side of the TEC to another side of the TEC. The UUT is disposed on the temperature-controlled side of the TEC, typically with a thermal interface material (TIM) disposed between the UUT and the TEC, and a heatsink is disposed on the other side of the TEC. By controlling the power supplied to the TEC, the amount of thermal energy flow across the TEC can be controlled, thereby controlling the UUT temperature. Instead of a heatsink, a cold plate may be used to remove heat from the thermal head assembly. Such a thermal head assembly 100 is shown in FIG. 1, including the TEC 102, the heatsink or cold plate 104, a pedestal structure or heat slug 105, and the TIM 106 in thermal contact with the UUT 50, as well as the associated controller 108. In some cases, the UUT 50 is disposed directly adjacent to the TEC 102, while in other cases, the pedestal structure or heat slug 105 is disposed between the UUT 50 and the TEC 102, serving to thermally couple the UUT 50 to the TEC 102 via the material and shape of the pedestal structure or heat slug 105. For example, the pedestal structure or heat slug 105 may be a solid copper block. The TIM 106 may be disposed between some or all of these components. In any case, as components get smaller and higher power, the TEC needs to be larger and more powerful, or more TECs need to be used since the TECs get much less efficient when cooling at low testing temperatures (i.e., the coefficient of performance (COP) drops, as shown in FIG. 2). This makes the thermal head much larger and more complex. Larger thermal head size is a problem since there are typically other testing connections that need to be made in the limited space around the UUT. Further, at low temperature set points there is a large temperature delta between the control side and the other side of the TEC and, at these large temperature deltas, the COP normally drops, which means such TECs become very energy inefficient and cooling power decreases so even larger heatsinks/cold plates are needed to reject the heat.

The present background is provided as illustrative environmental context only. It will be readily apparent to those of ordinary skill in the art that the concepts and principles of the present disclosure may be implemented in other environmental contexts equally, without limitation.

### SUMMARY

The present disclosure provides an improved method of controlling the testing temperature of a UUT using an improved thermal head assembly utilizing a TEC. This enables the testing of high-power optical sub-assemblies and the like at different temperatures to ensure functionality, as well as testing/calibration at multiple different temperatures to ensure that the products work well in any intended working temperature ranges and to weed out bad parts before putting them into another assembly or sub-assembly. The method and thermal head assembly of the present disclosure can apply to the thermal testing of any assembly (electronic or not), including very high speed computer components or other components that require very precise temperature control during operation.

Often, components and assemblies are tested at or close to their extreme operating temperature ranges and a common operating temperature range (i.e., the testing setpoint may be near the lowest operating temperature, near the normal operating temperature, and near the highest operating temperature). The UUT power, power density, and lowest testing temperature often determine the maximum amount of cooling power needed for testing.

The electronic component testing assembly of the present disclosure includes a pedestal with an integrated cold plate, a TEC, and a heatsink or cold plate (i.e., a heat dissipating member) for heat rejection. In use, the testing assembly controls the lowest temperature of the UUT where the most cooling power is required by the flow of coolant through the cold plate while the TEC is not necessarily used for any or at least most of the cooling (the TEC can be left off, the TEC can be used for fine temperature control, or the TEC can be used to heat the ambient side to prevent condensation, etc.). For higher test temperatures where less cooling power is used, the coldplate coolant flow is not necessarily needed, and the TEC can be used to control the test temperatures. Thus, when dealing with low testing temperatures that have significant impact on the required testing power, the cold plate and the TEC are used in concert to provide the desired testing conditions.

Including an integrated cold plate on the UUT temperature control side of the TEC thermal head assembly enables low UUT testing temperatures and allows the use of a more compact and lower power TEC, and a lower quantity of TECs, in the TEC thermal head assembly. In practice, when cooling to lower testing temperatures where the control temperature of the TEC is lower than the heat rejection side of the TEC, the TEC COP is reduced. If a conventional TEC thermal head assembly is used to get to the lowest testing temperature setpoint, a larger or more powerful TEC would be required, or more than one TEC would have to be used. This is impractical in many applications since UUTs are getting smaller and more powerful.

By putting an integrated cold plate on the control side of the TEC, lower testing temperatures can be achieved without needing an oversized TEC or more TECs, and the TECs used can be designed for use in the temperature/power ranges in which they are more efficient. If there is only one set point for the chiller associated with the cold plate, multiple testing stations can use the same chiller with a simple on/off for the coolant when needed to test to the lowest testing temperature setpoint and then the TEC can be used for other test temperature set points.

In some embodiments, the present disclosure provides a thermal testing assembly for an electronic component, the thermal testing assembly including a thermoelectric cooler having a temperature control side and a heat rejection side, a pedestal structure including an integrated cold plate disposed on and in thermal communication with the temperature control side of the thermoelectric cooler, and a heatsink and/or cold plate (i.e., a heat dissipating member) disposed on and in thermal communication with the heat rejection side of the thermoelectric cooler, where the thermoelectric cooler and/or the integrated cold plate are adapted to be operated to control a temperature of a unit under test disposed adjacent to and in thermal communication with the pedestal structure opposite the thermoelectric cooler. The thermal testing assembly further includes a thermal interface material disposed between the pedestal structure and the unit under test. In some embodiments, coolant from a chiller is circulated through the integrated cold plate to cool the unit under test through the pedestal structure. In some embodiments, when the coolant is circulated through the integrated cold plate to cool the unit under test through the pedestal structure, the thermoelectric cooler is not operated. In some embodiments, when the coolant is circulated through the integrated cold plate to cool the unit under test through the pedestal structure, the thermoelectric cooler is operated to fine tune the temperature of the unit under test. In some embodiments, when the coolant is circulated through the integrated cold plate to cool the unit under test through the pedestal structure, the thermoelectric cooler is operated to heat the heat rejection side of the thermoelectric cooler to prevent condensation. In some embodiments, the thermoelectric cooler is operated to cool the unit under test through the pedestal structure and coolant disposed within the integrated cold plate. In some embodiments, when the thermoelectric cooler is operated to cool the unit under test through the pedestal structure and the coolant disposed within the integrated cold plate, a chiller coupled to the integrated cold plate is not operated. In some embodiments, the thermoelectric cooler is operated to heat the unit under test through the pedestal structure and coolant disposed within the integrated cold plate. In some embodiments, when the thermoelectric cooler is operated to heat the unit under test through the pedestal structure and the coolant disposed within the integrated cold plate, a chiller coupled to the integrated cold plate is not operated. The thermal testing assembly further includes a controller adapted to control operation of the thermoelectric cooler and one or more chillers coupled to the integrated cold plate and cold plate, when used. The thermal testing assembly further includes a testing frame structure supporting the thermoelectric cooler, the pedestal structure, and the heatsink and/or cold plate, as well as the unit under test during thermal testing.

In some embodiments, the present disclosure provides a thermal testing method for an electronic component, the thermal testing method including providing a thermoelectric cooler having a temperature control side and a heat rejection side, providing a pedestal structure including an integrated cold plate disposed on and in thermal communication with the temperature control side of the thermoelectric cooler, and providing a heatsink and/or cold plate (i.e., a heat dissipating member) disposed on and in thermal communication with the heat rejection side of the thermoelectric cooler, where the thermoelectric cooler and/or the integrated cold plate are adapted to be operated to control a temperature of a unit under test disposed adjacent to and in thermal communication with the pedestal structure opposite the thermoelectric cooler. The thermal testing method further includes providing a thermal interface material disposed between the pedestal structure and the unit under test. In some embodiments, the thermal testing method includes circulating coolant from a chiller through the integrated cold plate to cool the unit under test through the pedestal structure. In some embodiments, when the coolant is circulated through the integrated cold plate to cool the unit under test through the pedestal structure, the thermoelectric cooler is not operated. In some embodiments, when the coolant is circulated through the integrated cold plate to cool the unit under test through the pedestal structure, the thermoelectric cooler is operated to fine tune the temperature of the unit under test. In some embodiments, when the coolant is circulated through the integrated cold plate to cool the unit under test through the pedestal structure, the thermoelectric cooler is operated to heat the heat rejection side of the thermoelectric cooler to prevent condensation. In some embodiments, the thermal testing method includes operating the thermoelectric cooler to cool the unit under test through the pedestal structure and coolant disposed within the integrated cold plate, where, when the thermoelectric cooler is operated to cool the unit under test through the pedestal structure and the coolant disposed within the integrated cold plate, a chiller coupled to the integrated cold plate is not operated. In some embodiments, the thermal testing method includes operating the thermoelectric cooler to heat the unit under test through the pedestal structure and coolant disposed within the integrated cold plate, where, when the thermoelectric cooler is operated to heat the unit under test through the pedestal structure and the coolant disposed within the integrated cold plate, a chiller coupled to the integrated cold plate is not operated.

It will be readily apparent to those of ordinary skill in the art that aspects and features of the various described embodiments may be included, omitted, or combined as desired in a given application, without limitation.

### BRIEF DESCRIPTION OF THE DRAWINGS

The present disclosure is illustrated and described with reference to the various drawings, in which like reference numbers are used to denote like assembly components/method steps, as appropriate, and in which:

FIG. 1 is a schematic view of a thermal testing head assembly utilizing a TEC and a heat rejection side heat sink or cold plate for the thermal testing of a UUT;

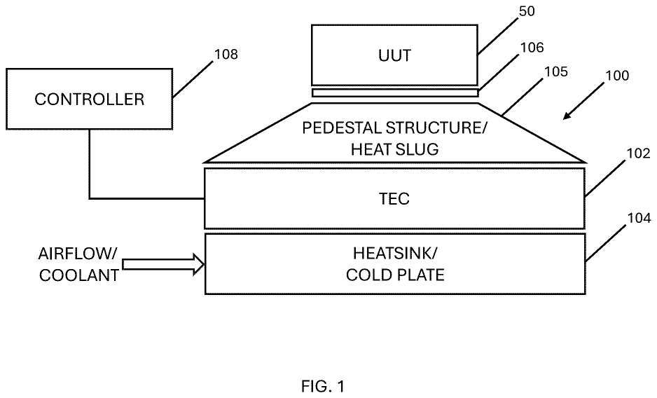

FIG. 2 is a series of plots showing how the COP of a TEC drops when cooling at low testing temperatures;

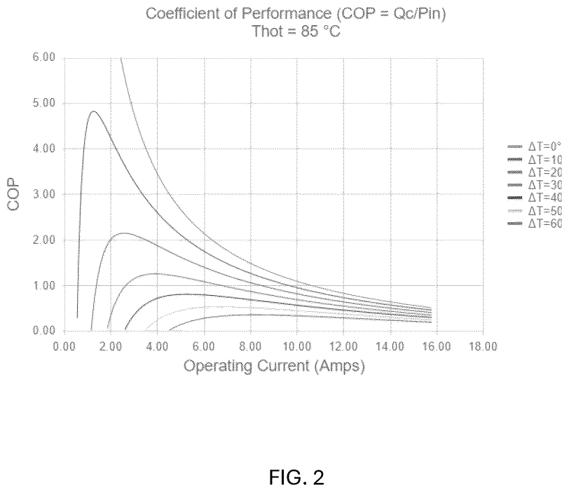

FIG. 3 is a perspective view of one embodiment of the thermal testing head assembly of the present disclosure utilizing a TEC, a temperature control side pedestal with an integrated cold plate, and a heat rejection side heat sink or cold plate for the thermal testing of a UUT;

FIG. 4 is a flowchart showing one embodiment of the method for providing the thermal testing head assembly of the present disclosure;

FIG. 5 is a flowchart showing one embodiment of the method for operating the thermal testing head assembly of the present disclosure; and

FIG. 6 is flowcharts showing other embodiments of the method for operating the thermal testing head assembly of the present disclosure.

It will be readily apparent to those of ordinary skill in the art that aspects and features of the various illustrated embodiments may be included, omitted, or combined as desired in a given application, without limitation.

### DETAILED DESCRIPTION

Again, the present disclosure provides an improved method of controlling the testing temperature of a UUT using an improved thermal head assembly utilizing a TEC. This enables the testing of high-power optical sub-assemblies and the like at different temperatures to ensure functionality, as well as testing/calibration at multiple different temperatures to ensure that the products work well in any intended working temperature ranges and to weed out bad parts before putting them into another assembly or sub-assembly.

Often, components and assemblies are tested at or close to their extreme operating temperature ranges and a common operating temperature range (i.e., the testing setpoint may be near the lowest operating temperature, near the normal operating temperature, and near the highest operating temperature). The UUT power, power density, and lowest testing temperature often determine the maximum amount of cooling power needed for testing.

The electronic component testing assembly of the present disclosure includes a pedestal with an integrated cold plate, a TEC, and a heatsink or cold plate (i.e., a heat dissipating member) for heat rejection. In use, the testing assembly controls the lowest temperature of the UUT where the most cooling power is required by the flow of coolant through the cold plate while the TEC is not necessarily used for any or at least most of the cooling (the TEC can be left off, the TEC can be used for fine temperature control, or the TEC can be used to heat the ambient side to prevent condensation, etc.). For higher test temperatures where less cooling power is used, the cold plate coolant flow is not necessarily needed, and the TEC can be used to control the test temperatures. Thus, when dealing with low testing temperatures that have significant impact on the required testing power, the cold plate and the TEC are used in concert to provide the desired testing conditions.

Including an integrated cold plate on the UUT temperature control side of the TEC thermal head assembly enables low UUT testing temperatures and allows the use of a more compact and lower power TEC, and a lower quantity of TECs, in the TEC thermal head assembly. In practice, when cooling to lower testing temperatures where the control temperature of the TEC is lower than the heat rejection side of the TEC, the TEC COP is reduced. If a conventional TEC thermal head assembly is used to get to the lowest testing temperature setpoint, a larger or more powerful TEC would be required, or more than one TEC would have to be used. This is impractical in many applications since UUTs are getting smaller and more powerful.

By putting an integrated cold plate on the control side of the TEC, lower testing temperatures can be achieved without needing an oversized TEC or more TECs, and the TECs used can be designed for use in the temperature/power ranges in which they are more efficient. If there is only one set point for the chiller associated with the cold plate, multiple testing stations can use the same chiller with a simple on/off for the coolant when needed to test to the lowest testing temperature setpoint and then the TEC can be used for other test temperature set points.

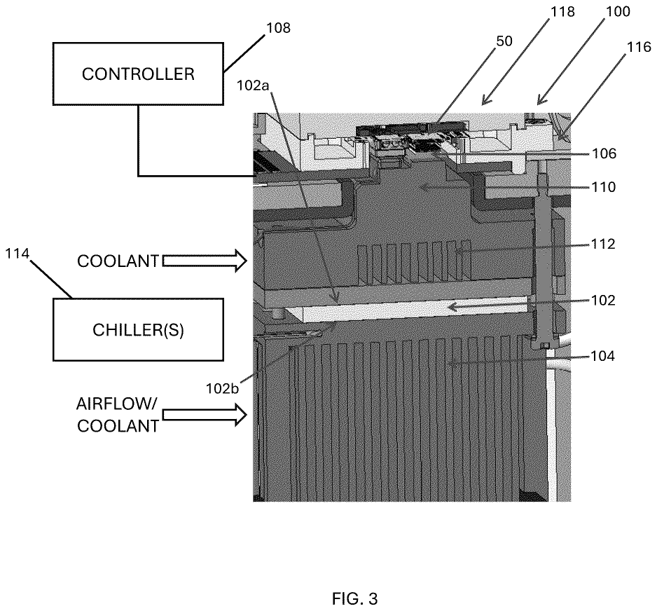

Referring to FIG. 3, in one embodiment, the thermal testing assembly 100 (or thermal testing head assembly 100) for the UUT 50 includes the TEC 102 having the temperature control side 102a and the heat rejection side 102b (or ambient side 102b). TECs, also known as Peltier coolers, are well known to those of ordinary skill in the art and use electricity to move heat from one side of the device to the other side of the device. This creates a temperature difference that cools one side of the device while heating the other side of the device. Thus, such TECs may alternatively be used as coolers or heaters, depending on how they are operated.

The pedestal structure 110 is disposed on and is in thermal communication with the temperature control side 102a of the TEC 102, whether the TEC 102 is used as a cooler or a heater. The pedestal structure 110 is manufactured from a thermally conductive material, such as a metallic material, a ceramic material, or the like, may be integrally formed or assembled from multiple components, and includes an integrated cold plate 112. The integrated cold plate 112 includes a coolant flow path disposed or defined within the pedestal structure 110 through which coolant from a chiller 114 is selectively circulated to cool the pedestal structure 110, and the UUT 50, to a desired temperature when the chiller is operated at the direction of the controller 108. The coolant flow path may be a simple conduit or may form a circuitous path through a portion or most of the pedestal structure 110. It should be noted that such cold plates arrangements are well known to those of ordinary skill in the art, although not in the context of a testing pedestal structure as provided here.

The heatsink and/or the cold plate 104 is/are disposed on and in thermal communication with the heat rejection side 102b of the TEC 102, serving to remove heat from the TEC 102 to the surrounding environment when the TEC 102 is used to cool the UUT 50, for example. In such a case, the heatsink 104 may be exposed to a cooling airflow from a fan, for example. The cold plate 104 may receive a coolant flow from a chiller 114, for example, like the integrated cold plate 112, although one or multiple chillers 114 may be utilized.

Typically, a portion of the pedestal structure 110 is thermally coupled to the UUT 50 through an intervening TIM 106, such as a thermal pad, copper contact surface, and/or the like.

The controller 108 is adapted to control operation of the TEC 102 and the one or more chillers 114 coupled to the integrated cold plate 112 and the cold plate 104, when used, depending on the desired testing conditions in terms of temperature and time. For example, the UUT 50 may be tested prior to or during operation under cold temperature conditions (e.g., at 0-15 C), moderate temperature conditions (e.g., around 45 C), and hot temperature conditions (e.g., around 85 C).

The thermal testing assembly 100 further includes a testing frame structure 116 that supports the TEC 102, the pedestal structure 110, and the heatsink and/or cold plate 104, as well as the UUT 50 during thermal testing. The UUT 50 may be coupled to a moveable stage 118 or the like also coupled to the testing frame structure 116. It will be readily apparent to those of ordinary skill in the art that other components and/or arrangements may be used equally, depending on the given application, type of UUT 50, space constraints, etc.

As described in greater detail below, the TEC 102 and/or the integrated cold plate 112 are adapted to be operated to control a temperature of the UUT 50 disposed adjacent to and in thermal communication with the pedestal structure 110 opposite the TEC 102.

In some embodiments, coolant from the chiller 108 is circulated through the integrated cold plate 112 to cool the UUT 50 through the pedestal structure 110. This is the case when thermally testing the UUT 50 in the lowest testing temperature ranges. By relying on the use of the integrated cold plate 112, and not the TEC 102, this allows a less expensive, more efficient TEC 102 to be used and prevents any TEC performance degradation that may otherwise be experienced. In some such embodiments, when the coolant is circulated through the integrated cold plate 112 to cool the UUT 50 through the pedestal structure 110, the TEC 102 is not operated. In some embodiments, when the coolant is circulated through the integrated cold plate 112 to cool the UUT 50 through the pedestal structure 110, the TEC 102 is operated to fine tune the temperature of the UUT 50, either helping to add to or subtract from the cooling of the integrated cold plate 112 on a granular level. In some embodiments, when the coolant is circulated through the integrated cold plate 112 to cool the UUT 50 through the pedestal structure 110, the TEC 102 is operated to heat the heat rejection side 102b of the TEC 102 to prevent condensation.

In some embodiments, the TEC 102 is operated to cool the UUT 50 through the pedestal structure 110 and coolant disposed within the integrated cold plate 112. In some embodiments, when the TEC 102 is operated to cool the UUT 50 through the pedestal structure 110 and the coolant disposed within the integrated cold plate 112, the chiller 108 coupled to the integrated cold plate 112 is not operated, such that the coolant is simply present within the integrated cold plate 112 and cooled by the TEC 102 with the pedestal structure 110. In some embodiments, the TEC 102 is operated to heat the UUT 50 through the pedestal structure 110 and coolant disposed within the integrated cold plate 112. In some embodiments, when the TEC 102 is operated to heat the UUT 50 through the pedestal structure 110 and the coolant disposed within the integrated cold plate 112, the chiller 108 coupled to the integrated cold plate 112 is not operated, such that the coolant is simply present within the integrated cold plate 112 and heated by the TEC 102 with the pedestal structure 110.

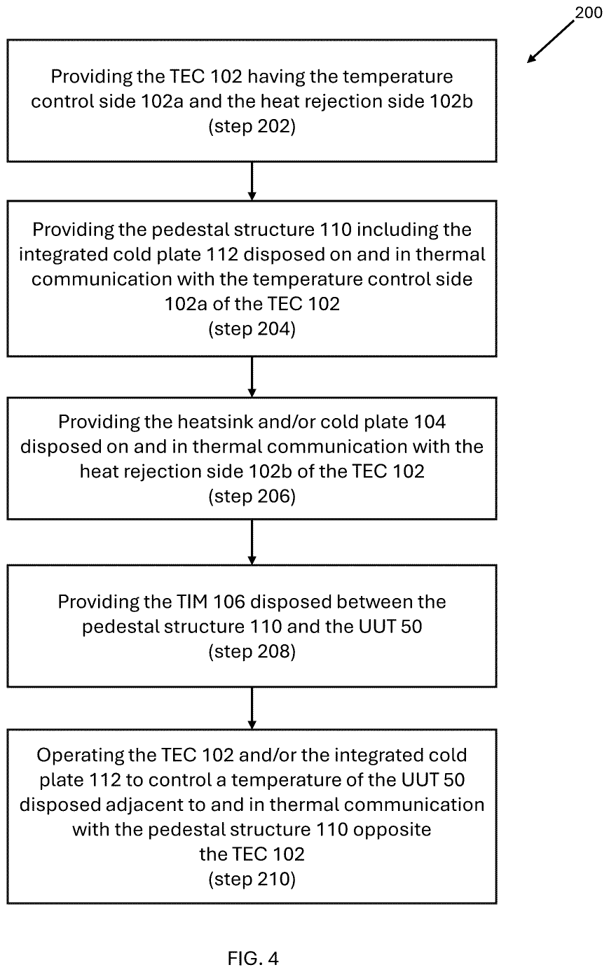

Referring to FIG. 4, the present disclosure provides a thermal testing method 200 for the electronic component 50 (i.e., the UUT 50), the thermal testing method including providing the TEC 102 having the temperature control side 102a and the heat rejection side 102b (step 202), providing the pedestal structure 110 including the integrated cold plate 112 disposed on and in thermal communication with the temperature control side 102a of the TEC 102 (step 204), providing the heatsink and/or cold plate 104 disposed on and in thermal communication with the heat rejection side 102b of the TEC 102 (step 206), and operating the TEC 102 and/or the integrated cold plate 112 to control a temperature of the UUT 50 disposed adjacent to and in thermal communication with the pedestal structure 110 opposite the TEC 102 (step 210). The thermal testing method 200 may further include providing the TIM 106 disposed between the pedestal structure 110 and the UUT 50 (step 208).

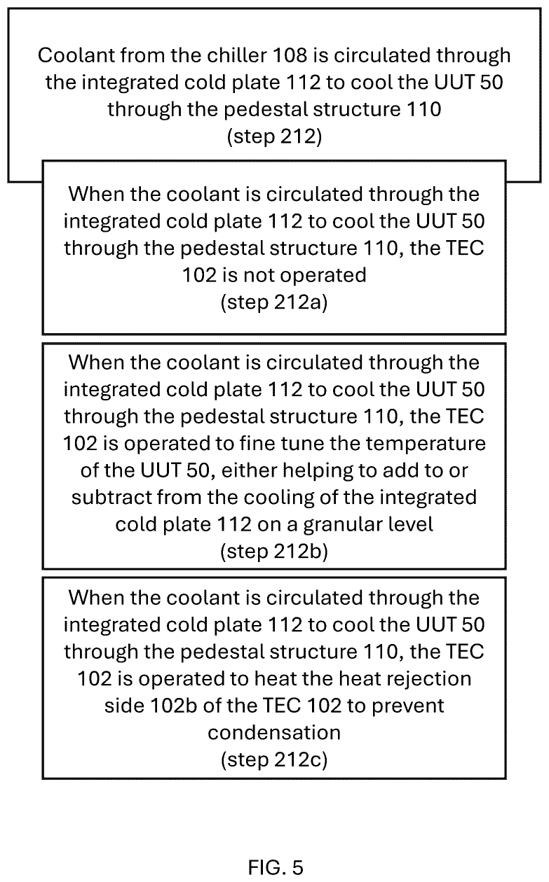

Referring to FIG. 5, in some embodiments, coolant from the chiller 108 is circulated through the integrated cold plate 112 to cool the UUT 50 through the pedestal structure 110 (step 212). Again, this is the case when thermally testing the UUT 50 in the lowest testing temperature ranges. By relying on the use of the integrated cold plate 112, and not the TEC 102, this allows a less expensive, more efficient TEC 102 to be used and prevents any TEC performance degradation that may otherwise be experienced. In some such embodiments, when the coolant is circulated through the integrated cold plate 112 to cool the UUT 50 through the pedestal structure 110, the TEC 102 is not operated (step 212a). In some embodiments, when the coolant is circulated through the integrated cold plate 112 to cool the UUT 50 through the pedestal structure 110, the TEC 102 is operated to fine tune the temperature of the UUT 50, either helping to add to or subtract from the cooling of the integrated cold plate 112 on a granular level (step 212b). In some embodiments, when the coolant is circulated through the integrated cold plate 112 to cool the UUT 50 through the pedestal structure 110, the TEC 102 is operated to heat the heat rejection side 102b of the TEC 102 to prevent condensation (step 212c).

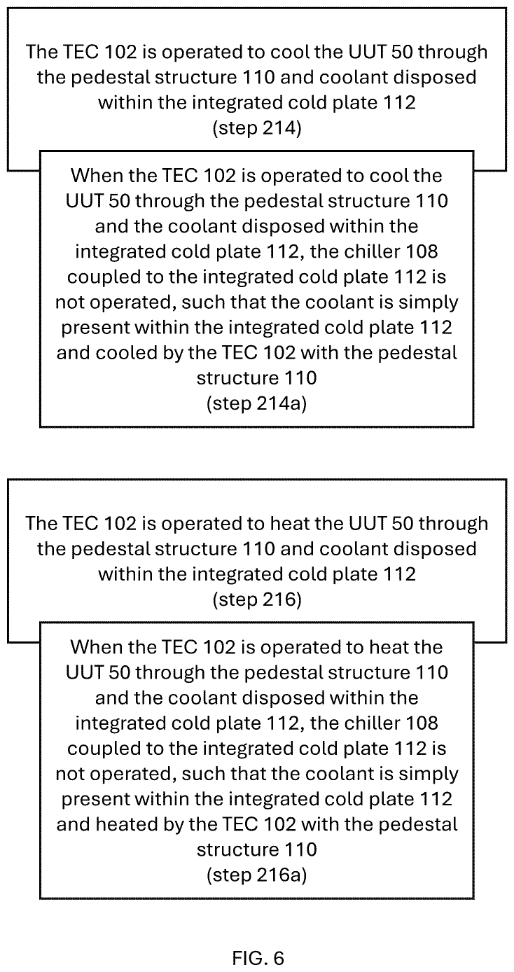

Referring to FIG. 6, in some embodiments, the TEC 102 is operated to cool the UUT 50 through the pedestal structure 110 and coolant disposed within the integrated cold plate 112 (step 214). In some embodiments, when the TEC 102 is operated to cool the UUT 50 through the pedestal structure 110 and the coolant disposed within the integrated cold plate 112, the chiller 108 coupled to the integrated cold plate 112 is not operated, such that the coolant is simply present within the integrated cold plate 112 and cooled by the TEC 102 with the pedestal structure 110 (step 214a). In some embodiments, the TEC 102 is operated to heat the UUT 50 through the pedestal structure 110 and coolant disposed within the integrated cold plate 112 (step 216). In some embodiments, when the TEC 102 is operated to heat the UUT 50 through the pedestal structure 110 and the coolant disposed within the integrated cold plate 112, the chiller 108 coupled to the integrated cold plate 112 is not operated, such that the coolant is simply present within the integrated cold plate 112 and heated by the TEC 102 with the pedestal structure 110 (step 216a).

It should be noted that any type of electronic component may be the UUT 50, such as a high-power optical component or the like—any electronic that can be thermally coupled to a heatsink or cold plate can be thermally coupled to the pedestal structure 110 of the present disclosure. It should also be noted that the UUT 50 may be a non-electronic component equally, and the testing of such non-electronic components is also contemplated by the present disclosure. Aside from the advantages described above, the thermal testing assembly 100 and method 200 of the present disclosure allow for a reduction in thermal testing time and an increase in slots per testing station. Conventional approaches require a long testing temperature ramp to achieve low calibration temperatures (as the TEC efficiency drops, more complex controllers 108 and programming are needed). The approach of the present disclosure allows for faster testing temperature ramps with almost no risk of TEC runaway. This means that the density of testing fixtures can be increased and reduced testing costs and testing times are enabled.

Although the present disclosure is illustrated and described with reference to illustrative embodiments and examples, it will be readily apparent to those of ordinary skill in the art that other embodiments and examples may perform similar functions and/or achieve like results. All such equivalent embodiments and examples are within the spirit and scope of the present disclosure, are contemplated thereby, and are intended to be covered by the following non-limiting claims for all purposes.

What is claimed is:

1. A thermal testing assembly for a component, the thermal testing assembly comprising
a thermoelectric cooler having a temperature control side and a heat rejection side,
a pedestal structure comprising an integrated cold plate disposed on and in thermal communication with the temperature control side of the thermoelectric cooler, and
a heat dissipating member disposed on and in thermal communication with the heat rejection side of the thermoelectric cooler,
wherein the thermoelectric cooler and/or the integrated cold plate are adapted to be operated to control a temperature of a unit under test disposed adjacent to and in thermal communication with the pedestal structure opposite the thermoelectric cooler.

2. The thermal testing assembly of claim 1, further comprising a thermal interface material disposed between the pedestal structure and the unit under test.

3. The thermal testing assembly of claim 1, wherein coolant from a chiller is circulated through the integrated cold plate to cool the unit under test through the pedestal structure.

4. The thermal testing assembly of claim 3, wherein, when the coolant is circulated through the integrated cold plate to cool the unit under test through the pedestal structure, the thermoelectric cooler is not operated.

5. The thermal testing assembly of claim 3, wherein, when the coolant is circulated through the integrated cold plate to cool the unit under test through the pedestal structure, the thermoelectric cooler is operated to fine tune the temperature of the unit under test.

6. The thermal testing assembly of claim 3, wherein, when the coolant is circulated through the integrated cold plate to cool the unit under test through the pedestal structure, the thermoelectric cooler is operated to heat the heat rejection side of the thermoelectric cooler to prevent condensation.

7. The thermal testing assembly of claim 1, wherein the thermoelectric cooler is operated to cool the unit under test through the pedestal structure and coolant disposed within the integrated cold plate.

8. The thermal testing assembly of claim 7, wherein, when the thermoelectric cooler is operated to cool the unit under test through the pedestal structure and the coolant disposed within the integrated cold plate, a chiller coupled to the integrated cold plate is not operated.

9. The thermal testing assembly of claim 1, wherein the thermoelectric cooler is operated to heat the unit under test through the pedestal structure and coolant disposed within the integrated cold plate.

10. The thermal testing assembly of claim 9, wherein, when the thermoelectric cooler is operated to heat the unit under test through the pedestal structure and the coolant disposed within the integrated cold plate, a chiller coupled to the integrated cold plate is not operated.

11. The thermal testing assembly of claim 1, further comprising a controller adapted to control operation of the thermoelectric cooler and one or more chillers coupled to the integrated cold plate and cold plate, when used.

12. The thermal testing assembly of claim 1, further comprising a testing frame structure supporting the thermoelectric cooler, the pedestal structure, and the heat dissipating member, as well as the unit under test during thermal testing.

13. A thermal testing method for a component, the thermal testing method comprising
providing a thermoelectric cooler having a temperature control side and a heat rejection side,
providing a pedestal structure comprising an integrated cold plate disposed on and in thermal communication with the temperature control side of the thermoelectric cooler, and
providing a heat dissipating member disposed on and in thermal communication with the heat rejection side of the thermoelectric cooler,
wherein the thermoelectric cooler and/or the integrated cold plate are adapted to be operated to control a temperature of a unit under test disposed adjacent to and in thermal communication with the pedestal structure opposite the thermoelectric cooler.

14. The thermal testing method of claim 13, further comprising providing a thermal interface material disposed between the pedestal structure and the unit under test.

15. The thermal testing method of claim 13, further comprising circulating coolant from a chiller through the integrated cold plate to cool the unit under test through the pedestal structure.

16. The thermal testing method of claim 15, wherein, when the coolant is circulated through the integrated cold plate to cool the unit under test through the pedestal structure, the thermoelectric cooler is not operated.

17. The thermal testing method of claim 15, wherein, when the coolant is circulated through the integrated cold plate to cool the unit under test through the pedestal structure, the thermoelectric cooler is operated to fine tune the temperature of the unit under test.

18. The thermal testing method of claim 15, wherein, when the coolant is circulated through the integrated cold plate to cool the unit under test through the pedestal structure, the thermoelectric cooler is operated to heat the heat rejection side of the thermoelectric cooler to prevent condensation.

19. The thermal testing method of claim 13, further comprising operating the thermoelectric cooler to cool the unit under test through the pedestal structure and coolant disposed within the integrated cold plate, wherein, when the thermoelectric cooler is operated to cool the unit under test through the pedestal structure and the coolant disposed within the integrated cold plate, a chiller coupled to the integrated cold plate is not operated.

20. The thermal testing method of claim 13, further comprising operating the thermoelectric cooler to heat the unit under test through the pedestal structure and coolant disposed within the integrated cold plate, wherein, when the thermoelectric cooler is operated to heat the unit under test through the pedestal structure and the coolant disposed within the integrated cold plate, a chiller coupled to the integrated cold plate is not operated.
